(19) United States
(12) Patent Application Publication
(10) Pub. No.: US 2012/0204953 A1
(43) Pub. Date: Aug. 16, 2012

(54) OPTICAL STRUCTURE WITH A FLAT APEX

(75) Inventors: Ko Hermans, Nederweert (NL); Benjamin Slager, Rhenen (NL)

(73) Assignee: SOLAREXCEL B.V., Venray (NL)

(21) Appl. No.: 13/500,739

(22) PCT Filed: Oct. 8, 2010
(86) PCT No.: PCT/EP10/65054

§ 371 Date: Apr. 6, 2012

(30) Foreign Application Priority Data
Oct. 8, 2009 (EP) 09172546.5

(51) Int. Cl. H01L 31/0232

(52) U.S. Cl. 136/257; 136/259

(57) ABSTRACT

A photovoltaic device having at least one active layer and a cover plate that contains on one side an array of optical structures and that is in optical contact with the light receiving surface of the active layer(s) in order to reduce the reflection losses of the surface. The plate or sheet may also be used in combination with luminescent molecules, which are inside or in contact with the plate, to improve the spectral response of the photovoltaic device. The optical relief structures having a base and a single flat apex that are connected by at least three n-polygonal surfaces where n is equal to 5 or higher.

The invention pertains to a photovoltaic device which comprises at least one active layer and a cover plate that contains on at least one side an array of optical structures and which is in optical contact with the light receiving surface of the active layer(s) in order to reduce the reflection losses of said surface. Said plate or sheet may also be used in combination with luminescent molecules, which are inside or in contact with said plate, to improve the spectral response of the photovoltaic device.

Photovoltaic devices are commonly used to convert light energy into electrical energy. These devices contain an active layer which consists of a light absorbing material which generates charge carriers upon light exposure. An active layer which is currently common in photovoltaic devices is silicon. However, a variety of materials can be encountered like for example gallium arsenide (GaAs), cadmium telluride (CdTe) or copper indium gallium diselenide (CIGS). The charges, which are generated in the active layer, are separated to conductive contacts that will transmit electricity. Due to the thin and brittle nature of the active layer it is usually protected from external influences by a transparent cover plate e.g. made of glass. It is known from the art that both the active layer and the cover plate reflect a part of the light incident to the photovoltaic device. Especially the high refractive index of the active layer causes large reflection losses which can—in the case of silicon—be up to 22% of the incident light. Since the reflected light can not be converted into electrical energy these reflection losses cause a large reduction in the efficiency of a photovoltaic device.

Another effect which reduces the efficiency of a photovoltaic device is the low quantum efficiency of the active layer for usually short wavelengths, like for example ultra violet (UV) or blue light. This low response is caused by the band-gap of the material. The band gap refers to the energy difference between the top of the valence band and the bottom of the conduction band, where electrons are able to jump from one band to another. Due to the band-gap, the active layer has an optimal wavelength around which light energy is most efficiently converted into electrical energy. Light with a wavelength which is higher or lower than the optimum wavelength is less efficiently converted into electrical energy. A second effect which can reduce the spectral response of a photovoltaic device in the short wavelength range is the absorption of light by the cover plate. Although the cover plate is usually transparent to visible light it often absorbs in the UV range. As a result this light can not reach the active layer of the photo voltaic device and can not be converted into electrical energy.

In order to reduce these reflection losses, an anti reflection coating can be applied on top of the light absorbing material or so called active layer. An anti reflection coating consists of a single quarter-wave layer of a transparent material with a refractive index which is between the refractive index of the active layer and the cover plate. Although this theoretically gives zero reflectance at the center wavelength and decreased reflectance for wavelengths in a broad band around the center, the processing and material costs of these layers are relatively high. Also the processing techniques to create the coatings (e.g. chemical vapour deposition) are comprehensive and time consuming. In addition, the anti-reflection coating only works on the surface to which it is applied. It is therefore not possible to reduce both the reflection of the active layer and the cover plate by using one single anti reflection coating on either of these surfaces.

Another method to reduce the reflection losses is to structure the surface of the active layer. This can be done by either direct structuring of the material itself or by surface structuring of the substrate on which said material is deposited. By structuring the active layer, with commonly pyramid or V-shaped structures, a reduction in the reflection losses at active layer is obtained by multiple reflections at the surface offering the light a greater opportunity to enter the panel. This effect reduces the reflection losses at the surface of the active layer and is therefore often referred to as an anti-reflection effect. Secondly, the structures may in some cases partially trap the light which is not absorbed by the active layer and reflected by surface of the substrate. As a result the chance of light absorption by the active layer is increased. Although structuring of the active layer can significantly improve the efficiency of a photovoltaic cell, production methods are very complicated and extremely expensive. Often processes like wet chemical etching, mechanical etching or reactive ion etching are used to realize the desired effect. Also the structuring of the active layer does not reduce the reflection losses of the cover plate.

It is known from the art that the same concept as described in the previous paragraph can be used to improve the light transmission of a glass plate i.e. the cover plate. Here, V-shaped (G. A. Landis, 21^{st} IEEE photovoltaic specialist conference, 1304-1307 (1990)) or pyramidal structures as disclosed in WO 03/046617 are applied to a glass plate to reduce the reflection losses of said plate and hence increase its transmission. The structures can be applied to the glass plate via for example casting or pressing. However, when using the plate as a cover plate of a photovoltaic device the maximum efficiency of said device can only be increased by 6%, which is a reduction of approximately 30% of the reflection losses, according to a model study (U. Blieske et all, 3^{rd} World Conference on Photovoltaic Energy Conversion, 188-191 (2003)). In practice the results are even less and only 3% can be obtained. Although the structures reduce some of the reflection losses of the active layer, it reduces predominantly the reflection losses of the cover plate. Hence the total reduction in reflection losses, and increase in efficiency of the photovoltaic device, is low.

In document FR 2916901 and also in WO 2008/122047 a concentrator type structure is disclosed. The truncated optical structure of these documents are used to focus the light on solar cells attached to the flat apices of the truncated optical structure.

In document FR 2915834 a method for texturing the active layer of a solar panel is disclosed. In this method a layer of truncated optical structures is position between the glass and the active layer interface to texture the active layer.

In all cases of documents FR 2916901, WO 2008/122047 and FR 2915834 the solar cells are attached to the truncated optical structures. This means the truncated optical structures are connected with the active layer of the solar cells.

It is an object of the present invention to improve the efficiency of a photovoltaic device and to provide a photovoltaic device in which the reflection losses, especially the reflection losses of the active layer are further reduced without reducing the mechanical integrity of device and reducing its outdoor durability.

This object is achieved by a photovoltaic device comprising the features of claim 1.

The photovoltaic device comprises at least one active layer and a transparent cover plate which contains on one side an array of geometrical optical relief structures and which is in optical contact with a surface receiving side of the at least one active layer of a photovoltaic device, whereby the optical relief structures comprise a base and a single flat apex which are connected by at least three n-polygonal surfaces where n is equal to 3 or higher. Preferably n is equal to 4 or higher.

The photovoltaic device comprises at least one active layer and a transparent cover plate which contains on a first side an array of geometrical optical relief structures and which is with a second side in optical contact with a surface receiving side of the at least one active layer of a photovoltaic device, whereby the optical relief structures comprise a base and a single flat apex which are connected by at least three n-polygonal surfaces where n is equal to 3 or higher. Preferably n is equal to 4 or higher.

The first side and the second side of the cover plate are preferably approximately parallel to each other, whereby the first side is the opposite side of the second side.

The flat apex is defined as the upper area of a geometrical structure. The apex is a single small flat area, which is located at one or more of the surfaces of the structure. It is located where the length of a normal from the base crossing a surface of the structure is the longest.

The truncated part of the geometrical structure is preferably the flat apex of the geometrical structure. The truncated part or the flat apex is preferably not in direct contact with the active layer of the photovoltaic device.

Although the transparent cover plate could contain only one individual geometrical optical relief structure it is preferred that the transparent cover plate contains an array of geometrical optical relief structures. An array is to be understood as a collection or group of elements, in this case individual optical relief structures, placed adjacent to each other or arranged in rows and columns on one substrate. Preferably the array contains at least 4 geometrical optical relief structures.

Surprisingly it could be shown that the cover plate comprising the optical relief structures reduces the reflection losses of the light receiving surface of the active layer of a photovoltaic device, with the provision that said cover plate is placed in optical contact with the light receiving side of said active layer. If this requirement is not fulfilled the transmission through said plate to said active layer is reduced such that it is equal or lower than compared to a non structured surface.

It was further surprisingly found that a cover plate with optical relief structure with flat apex is less sensitive against mechanical stress like impacts. Due to this the cover plate itself is more robust and exhibits a longer lifetime then cover plates with peak apex structure.

Preferably, the optical relief structure comprises a base and a single flat apex which are connected with each other by at least three n-polygonal surfaces, where n is equal to 5 or higher.

Preferably the base of the optical relief structure comprises an m-sided polygonal shape and the optical structure contains in total of at least m+1 surfaces.

The optical relief structure according to the invention has two principle functions:
1. Light, which enters the structure via the n-sided polygonal base is at least partially reflected to its original direction by the surfaces of said structure.
2. Light, which enters the structure via the surfaces of said structure is at least partially transmitted.

In a preferred embodiment of the invention a single structure should preferably be converging over all surfaces, except the apex, of which the structure is comprised. It can be characterized that the angle between the base and any surface should be 90° or less.

In a preferred embodiment of the invention, the transparent cover plate contains an array of geometrical optical relief structures with adjacent structures abutting each other. The structures can be placed such that the orientation of all structures is the same, alternating or random with respect to each other.

When describing the n-polygonal base of the optical structure by a circle wherein the edges of the polygonal base lie on the circumferential line of the circle, the diameter D of the circle is preferably less than 30 mm, more preferably less than 10 mm and most preferably less than 3 mm.

The height of structures depends on the diameter D of the base and is preferably between 0.1*D and 2*D.

In a preferred embodiment of the photovoltaic device according to the invention the surfaces of the array of optical relief structures are covered with a coating. The coating may be an anti-fogging coating, anti-fouling coating, anti-scratch coating or the like.

In a more preferred embodiment of the photovoltaic device according to the invention the coating has a different refraction index than the optical relief structures and the shape of the coating is complementary to the array of geometrical optical relief structures and that the photovoltaic device with the coating has an even non-relief structures. For example, it is possible to create the optical relief structures in a high refractive index material and coat it with a low refractive index material such that there is no relief structure after coating. In other words, the high refractive optical relief structures are “filled” with low refractive index material.

The cover plate comprising the optical relief structures can be made of any transparent material. A transparent material is to be understood as a material which has a linear absorption of less than 0.2 mm⁻¹ within the range of 400-1200 nm. Preferably the optical relief structures are made of a polymeric material. Examples for polymeric materials are polycarbonate, polymethylmethacrylate, polypropylene, polyethylene, polyamide, polyacrylamide or any combinations thereof. The polymer is preferably stabilized by UV absorbers and/or hindered amine light stabilizers.

In another preferred embodiment the optical relief structures are made of a glass, e.g. silicate glass or quartz glass.

The thickness of the plate is preferably less than 30 mm, more preferably less than 10 and most preferably less than 3 mm.

The cover plate comprising the optical relief structures according to the invention may be obtained by processes known in the art, e.g. injection molding, thermo calendaring, laser structuring, photo-lithographic methods, powder pressing, casting, grinding or hot pressing.

To overcome the effect of low spectral response, especially of the lower wavelengths, of the active layer of a photovoltaic device luminescent dyes can be applied on or above the active layer. Said luminescent dyes improve the spectral response of the device by converting wavelengths which are not efficiently used by said layer to wavelengths which are more efficiently used. The luminescent molecules of the dye absorb short wavelengths and re-emit the light at a longer wavelength.

Therefore, the present invention also pertains a photovoltaic device as initially described in which a luminescent dye is present in the transparent cover plate that contains the array of optical relief structures.

Part of the light emitted by the luminescent molecules of the luminescent dye can however not be used by the active layer of prior art photovoltaic devices because it is directed away from the active layer, or because it is reflected by said layer due to its high refractive index. As a result luminescent dyes can in practice only increase the efficiency of prior art photovoltaic devices by approximately 2% (H. J. Hovel et all, Solar energy materials, 2, 19-29 (1979).

When combining a photovoltaic device according to the present invention with luminescent dyes known in the art, surprisingly a synergetic effect occurs in which the spectral response of a photovoltaic device is improved beyond what would be expected from the simple addition of luminescent molecules of the luminescent dye.

It should be noted, however, that when luminescent molecules are added to the transparent cover plate, said plate might become non transparent within a least a part of the wave length range between 400-1200 nm.

When adding luminescent molecules to the transparent cover plate comprising the optical relief structures according to the invention, the spectral response of the photovoltaic device is improved compared to a non structured surface (See FIG. 2). The transparent cover plate comprising the optical structures increases the absorption of light emitted by the luminescent molecules at the light receiving surface of the active layer of the photovoltaic device by reducing the reflection losses of luminescent light and redirecting luminescent light emitted away from the active layer back to the active layer. The luminescent molecules are preferably distributed inside the plate, but can also be present in a separate layer between the transparent cover plate which contains the array of optical relief structures and the light receiving surface of the active layer of the photovoltaic device. Optical contact between the transparent cover plate comprising the optical relief structures and/or the layer containing the luminescent molecules and the light receiving surface of the active layer of a photovoltaic device is required.

Also the array of optical structures according to the invention can reduce required the concentration of luminescent dye and layer thickness. The amount of light converted into another wavelength by a luminescent dye is related to the amount of light absorbed by said dye, which in its turn is related to the layer thickness and the dye concentration according to the Lamber-Beer law:

Absorbance=ε*[C]*l (1)

ε=molar extinction coefficient in [L mol⁻¹ cm⁻¹]
[C]=concentration of dye in [mol L⁻¹]
l=layer thickness in [cm].

To ensure that most of the incident light is absorbed, and thus the luminescent molecules are used optimally, either ε, l or [C] has to be large. Since ε is an intrinsic property of the dye and can not be altered, and [C] is limited since luminescent dyes have a limited solubility into a matrix materials such as polymers, it is thus necessary to have a thick layer (l). Due to the thick layer required and high costs of the luminescent dyes itself this is relatively expensive.

The synergetic effect of the luminescent molecules in combination with the array of optical structures according to the invention is thus not limited to an increase in output. The array of optical structures increases the path length of incident light through the layer containing the luminescent dye. As a result, a lower concentration of luminescent molecules and thinner layers can be used without a reduction in efficiency.

The luminescent molecules which may be used can for example be fluorescent or phosphorescent and said molecules can be both down-conversion luminescent and up-conversion luminescent. The preferred molecules are fluorescent and can for example be any perelyne, coumarin, rhodamine, naphthalimide, benzoxanthene, acridine, auramine, benzanthrone, cyanine, stilbene, rubrene, leciferin or derivatives thereof.

The luminescent dye containing the luminescent molecules is thus preferably an organic dye. The luminescent dye may, however, also be an inorganic dye. Preferably the luminescent dye acts as an UV absorber to stabilize the polymer building the transparent cover plate.

The luminescent dye may comprise a mixture of several luminescent dyes. The concentration of the luminescent dye preferably lies between 0.001 and 50 gram dye per m² cover plate surface and per mm cover plate thickness.

Whether optical contact is achieved depends on the refractive index (n) of the medium or media which connect the transparent plate comprising the array of optical relief structures and the photovoltaic device. If a medium between said components is non-existing optical contact is per definition achieved. In all other cases optical contact is achieved when the refractive index of the medium or media between the components is on average at least 1.2. More favorably the refractive index of the medium or media is on average at least 1.3 and most favorably the refractive index of the medium is at least 1.4. To determine the refractive index of a medium an Abbe refractometer should be used.

For example, in case the transparent cover plate comprising the array of optical structures is made of polymethylmethacrylate with n=1.5 (whereby n is the refractive index), the active layer of the photovoltaic device is made of silicon n=3.8 (whereby n is the refractive index) and the medium between these two components is air n=1 (whereby n is the refractive index) no optical contact is achieved.

In case the transparent cover plate comprising the array of optical structures is made of polymethylmethacrylate with n=1.5 (whereby n is the refractive index), the active layer of the photovoltaic device is made of silicon n=3.8 (whereby n is the refractive index) and the medium is an adhesive with a refractive index of n=1.5 (whereby n is the refractive index), optical contact is achieved.

Whether optical contact is achieved does not depend on the distance between the transparent cover plate and/or the layer comprising the luminescent molecules and the surface receiving surface of the active layer of a photovoltaic device.

The invention relates to a photovoltaic device comprising at least one active layer and a transparent cover plate which contains on at least one side an array of geometrical optical relief structures and which is in optical contact with a surface receiving side of the at least one active layer of a photovoltaic device, whereby the optical relief structures comprise a base and a single flat apex which are connected by at least three n-polygonal surfaces where n is equal to 3 or higher. In view of this invention also a plate containing on at least one side an array of geometrical optical relief structures with the purpose of using in combination with a photovoltaic device is under the scope of this invention.

The invention is further described by means the following figure.

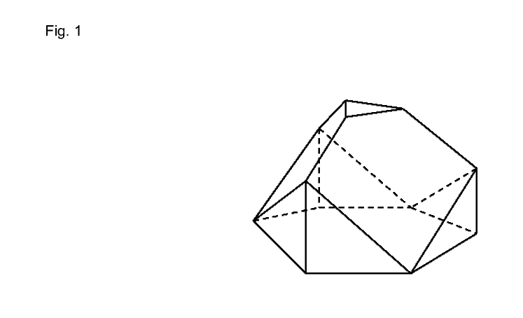

FIG. 1: shows schematically an optical structure comprising a base and a flat apex which are connected by at least three n-sided polygonal surfaces with n is equal to three or higher.

As shown in FIG. 1 the structure exhibits a flat apex, whereby the dimension of this flat apex is variable. The surface of the flat apex could be in the dimension of 1 micron to 10 mm, preferably 10 micron to 5 mm and most preferably 100 micron to 1 mm. It is preferred, that all points in the flat apex surface have the same distance relative to the base of the structure. Further, the surface of the flat apex (flat area) is located of which the distance to the base is the longest, measured in a straight line perpendicular to the base. This means all points building up the surface of the flat apex are located which the distance to the base is the longest, measured in a straight line perpendicular to the base.

1. A photovoltaic device comprising at least one active layer and a transparent cover plate which contains on one side an array of geometrical optical relief structures and which is in optical contact with a surface receiving side of the at least one active layer of a photovoltaic device, characterized in that the optical relief structures comprise a base and a single flat apex which are connected by at least three n-polygonal surfaces where n is equal to 3 or higher.

2. A photovoltaic device comprising at least one active layer and a transparent cover plate which contains on a first side an array of geometrical optical relief structures and which is with a second side in optical contact with a surface receiving side of the at least one active layer of a photovoltaic device, characterized in that the optical relief structures comprise a base and a single flat apex which are connected by at least three n-polygonal surfaces where n is equal to 3 or higher.

3. A photovoltaic device according to any one of claims 1 or 2, whereby the optical relief structure comprises a base and a single flat apex which are connected by at least three n-polygonal surfaces, where n is equal to 5 or higher.

4. A photovoltaic device according to any of the foregoing claims, characterized in that the base of the optical relief structure is of an m-sided polygonal shape and that the optical structure contains at least m+1 surfaces.

5. A photovoltaic device according to any of the foregoing claims, characterized in that the transparent cover plate contains an array of geometrical optical relief structures with adjacent structures abutting each other.

6. A photovoltaic device according to any of the foregoing claims, characterized in that the transparent cover plate contains an array of geometrical optical relief structures which have the same orientation, an alternating orientation or a random orientation with respect to each other.

7. A photovoltaic device according to any of the foregoing claims, characterized in that the surfaces of the array of optical relief structures are covered with a coating.

8. A photovoltaic device according to claim 7 characterized in that the coating has a different refraction index than the optical relief structures and that the shape of the coating is complementary to the array of geometrical optical relief structures and that the photovoltaic device with the coating has an even non-relief structures.

9. A photovoltaic device according to any of the foregoing claims, characterized in that the transparent cover plate which contains on one side an array of geometrical optical relief structures is made of a glass or polymeric material.

10. A photovoltaic device according to claim 9 characterized in that the polymer is polymethylmethacrylate or polycarbonate.

11. A photovoltaic device according to any one of claims 9 to 10 characterized in that the polymer is stabilized by UV absorbers and/or hindered amine light stabilizers.

12. A photovoltaic device according to any of the foregoing claims, characterized in that a luminescent dye is present in the transparent cover plate which contains the array of optical relief structures.

13. A photovoltaic device according to any of the foregoing claims, characterized in that a luminescent dye is present in a layer between the transparent cover plate which contains the array of optical relief structures and the light receiving surface of the active layer of the photovoltaic device.

14. A photovoltaic device according to any of the foregoing claims, characterized in that the concentration of luminescent dye lies between 0.001 and 50 gram dye per m² cover plate surface and per mm cover plate thickness.

15. A photovoltaic device according to any one of claims 13 to 14 characterized in that the luminescent dye is an organic dye or an inorganic dye.

16. A photovoltaic device according to any one of claims 13 to 15 characterized in that the luminescent dye acts as a UV absorber to stabilize the polymer provided that that the transparent cover plate which contains on at least one side an array of geometrical optical relief structures is made of a polymeric material.
